(19) United States
(12) Patent Application Publication
(10) Pub. No.: US 2022/0380602 A1
(43) Pub. Date: Dec. 1, 2022

(54) SYSTEM AND METHOD FOR HIGH RESOLUTION 3D NANOFABRICATION

(71) Applicant: Irradiant Technologies Inc., Cambridge, MA (US)

(72) Inventors: Daniel Oran, Cambridge, MA (US); Amos Meeks, Arlington, MA (US); Sheilan Sinjari, Cambridge, MA (US)

(21) Appl. No.: 17/826,076

(22) Filed: May 26, 2022

Related U.S. Application Data
(60) Provisional application No. 63/193,321, filed on May 26, 2021.

(51) Int. Cl. C09B 23/01; B29C 64/124; B29C 64/286; B33Y 30/00; B33Y 70/00; B82Y 40/00

(52) U.S. Cl. CPC C09B 23/0075; B29C 64/124; B29C 64/286; B33Y 30/00; B33Y 70/00; B82Y 40/00; B29K 2105/0061

(57) ABSTRACT

A system and method for nanofabrication that can enable complex three-dimensional nanostructures comprising: setting up a gel scaffold; patterning the gel scaffold with a photosensitive patterning material, wherein light is used to pattern the photosensitive patterning material into the gel scaffold to create the shape of a desired construct (i.e., creating a latent pattern of the desired constructs shape); depositing build material onto the latent pattern, thereby creating the construct; and shrinking the construct to the desired size. The system and method leverage the photosensitivity of the photosensitive molecule and high precision of light positioning for the fabrication of a high-resolution construct. The system and method may enable the fabrication of nano-constructs of simple and complex material designs, wherein the constructs may implement multiple distinct build materials and gradients of build materials.

### CROSS-REFERENCE TO RELATED APPLICATIONS

This Application claims the benefit of U.S. Provisional Application No. 63/193,321, filed on 26 May 2021, which is incorporated in its entirety by this reference.

### TECHNICAL FIELD

This invention relates generally to the field of nanofabrication, and more specifically to a new and useful system and method for three-dimensional nanofabrication.

### BACKGROUND

Nanofabrication is a technology that has become a significant part of our technology in the last century. It has become particularly significant in the fields of photonics, microprocessor development, microelectromechanical systems, and is gaining speed in other aspects of modern technology, such as biotechnology and microfluidics.

Current nanofabrication techniques are primarily derived from the planar process, wherein two-dimensional layers are built upon each other to produce a three-dimensional object. Although this method may work for some builds, the planar process fails in many aspects (e.g., for constructions that lack support to build upon) to be successful as true three-dimensional fabrication techniques; for this reason, it is considered a 2.5D fabrication technique. Additionally, current nanofabrication techniques have difficulty for creating objects made of multiple materials or to create objects that incorporate construction gradients. Lastly, methods derived from the planar process suffer from registration errors that result from imperfectly aligned sequential steps.

Thus, there is a need in the field of nanofabrication to create a new and useful system and method for true three-dimensional nanofabrication that can implement multiple materials and gradients. This invention provides such a new and useful system and method.

### BRIEF DESCRIPTION OF THE FIGURES

FIG. 1 is a schematic representation of an example system.

FIG. 2 is a list of example monomers that build the gel scaffold.

FIG. 3 is a representation of a xanthene core.

FIG. 4 is a general formulation for a polymethine core.

FIG. 5 is a general formulation for a cyanine structure.

FIG. 6 is a general formulation for a sulfonated dole-squaraine structure.

FIG. 7 is a general formulation for a benzothiazole squaraine.

FIG. 8 is a list of general formulations for example chromophores.

FIG. 9 is a flowchart of an example method.

FIG. 10 is a flowchart of a second example method.

### DESCRIPTION OF THE EMBODIMENTS

The following description of the embodiments of the invention is not intended to limit the invention to these embodiments but rather to enable a person skilled in the art to make and use this invention.

### 1. Overview

A system and method for nanofabrication can enable complex three-dimensional nanostructures with various materials. The system and method can employ a process of: patterning a gel scaffold with a photosensitive molecule, wherein light is used to pattern the photosensitive molecule into the gel scaffold to create the shape of a desired construct, thereby creating a latent pattern of the desired constructs shape; binding build material to the latent pattern, thereby creating the construct; and shrinking the construct to the desired size. The system and method leverage the photosensitivity of the photosensitive molecule and high precision of light positioning for the fabrication of a high-resolution construct. The system and method may enable the fabrication of nano-constructs of simple and complex material designs, wherein the constructs may implement multiple distinct build materials and gradients of build materials.

The system and method provide a large range of use cases in a variety of fields that may benefit from nanofabrication. The system and method may be implemented to build simple and complex tools in many general fields, such as: electronics, optics, and mechanics. The system and method may be used in production of nanofabricated electrical, optical, and/or mechanical components and combinations thereof.

As the system and method enable construction of nano-constructs with gradients and multiple materials, the system and method may be particularly useful in the field of optics and photonics. The system and method may be implemented for the building of wave guides, prisms, gratings, traditional lenses, Fresnel lenses, GRIN lenses, Meta-lenses, lens arrays, zone plates, inverse-design structures, photonic crystals, linear and circular polarizers, optical isolators, reflective optics (such as parabolic reflectors), optical cavities, lasers, and many other tools and objects as well as integrated combinations of these.

The system and method may provide a number of potential benefits. The system and method are not limited to always providing such benefits, and are presented only as exemplary representations for how the system and method may be put to use. The list of benefits is not intended to be exhaustive and other benefits may additionally or alternatively exist.

The system and method provide the benefit of true three-dimensional nanofabrication, wherein two-dimensional layering is not required for the fabrication.

The system and method can leverage the high precision of light beams to enable equally high precision positioning of build material for the creation of a high-resolution construct.

Additionally, the system and method enable an initial build of a “larger” construct prior to shrinking down the construct, providing even better construction precision.

The system and method provide the additional benefit of enabling multi-material constructions. Through the use of a ligand binding latent patterning, the system and method enable the use of multiple materials for a fabrication.

The system and method enable the implementation of concentration gradients of material within a construct. That is, the density of material may be varied through the construct by implementation of light positioning directed through material.

### 2. System

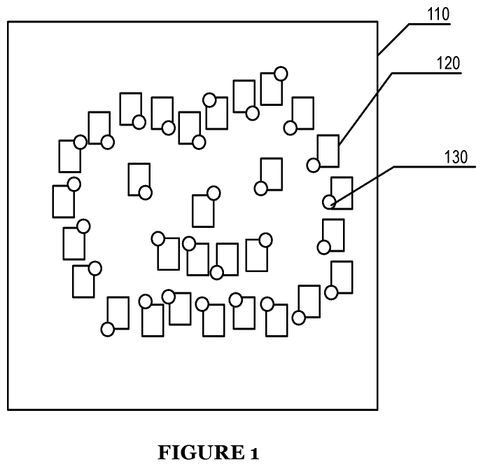

As shown in FIG. 1, a system for nanofabrication platform includes: a gel scaffold 110 that provides a framework to build the nanofabrication; a latent patterning material 120, that is photosensitive that selectively binds the gel scaffold, thereby providing the architecture of the nanofabrication; and a build material 130 that binds to the latent patterning material, thereby providing the composition material of the nanofabrication. The system functions as a nanofabrication assembly that enables fabrication of a desired construct (i.e., nanofabrication) with potentially nanometer precision, composed of a desired build material.

The system has many use cases and implementations. In certain embodiments, the system may further comprise a light based nanofabrication platform, wherein a light source may be incorporated to guide/enable nanofabrication. In this manner the system may function as an enhanced photon lithography device, wherein the system may be enabled to construct high precision film structures, in addition to constructing complex three-dimensional structures (with no limitations on any dimension). In these embodiments, the system may further include a light source (e.g., a laser), wherein the light source may be directed with high degree of accuracy onto any region of the gel scaffold 110. In variations where the system functions as an enhanced photolithography device, the system may further include a mask; wherein dependent on the desired nanofabrication implementation, the mask may be positioned to allow, block, or redirect, light from reaching certain parts of the gel scaffold 110.

As used herein, component names may be used to refer to components in any level of scaling. For example: the gel scaffold 110, may be used to refer to a single molecule of the gel scaffold, some set of molecules that make up all, or part, of the gel scaffold, or the entire gel scaffold. Thus, any reference to the gel scaffold 110 may refer to any of these scalings of the gel scaffold. The specific scaling of the component is provided by context if necessary.

The system may include a gel scaffold 110. The gel scaffold 110 functions as a multi-dimensional scaffold for nanofabrication. The gel scaffold 110 provides a scaffold network for the latent patterning material 120 to bind to. Herein, the term gel scaffold 110 may be used to refer to each individual gel scaffold molecule, a group of gel scaffold molecules, all gel scaffold molecules, or any subset therein.

The gel scaffold 110 may comprise any known, or future, “gel” material. As used herein gel material may refer to any colloidal solid (or semi-solid) polymer network; wherein the gel scaffold 110 comprises gel material that permits diffusion (active or passive) of other system components through the gel scaffold. Dependent on implementation, the gel scaffold 110 may be composed of one, or more, gel materials. Examples of possible gel materials include: agarose, acrylate (e.g. polyacrylate), methacrylates, acrylamide, and silicone.

In many variations, the gel scaffold 110 is unreactive with other system components other than the latent patterning material 120. Alternatively, the gel scaffold 110 may be reactive to other components. For example, in one variation the system may further include a masking component, wherein the gel scaffold may selectively bind the masking component. This selective binding (e.g., to the masking component) may block the gel scaffold to prevent the binding of the latent patterning material 120.

In many variations, the gel scaffold 110 may comprise a cross-linked (i.e., crosslinkers) polymer network. The gel scaffold 110 may have physical or covalent crosslinks, inherent or implemented, as part of the multidimensional gel scaffold. For example, a polyacrylate gel may have N,N′-Methylene-bis(acrylamide) cross-linkers. In some variations, this polymer network is generated from one, or more, vinyl monomers. The vinyl monomers may be acrylic or acrylamide monomers bearing side groups, wherein these side groups may, or may not, be inert to reaction with other system components, other than latent patterning material 120. In some variations, the gel scaffold 110 is covalently cross-linked via radical polymerization with a diacrylamide monomer. In other variations, dimethacrylamides, diacrylates, dimethacrylates, divinylethers, and suitable hydrophobic or hydrophilic divinyl monomers may be used to generate covalent cross-links.

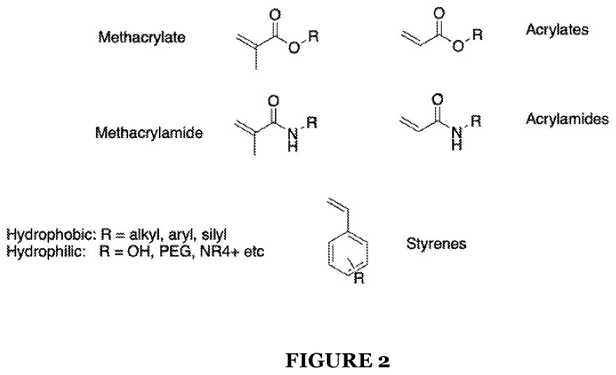

In some variations, the gel scaffold 110 may be composed of hydrophobic, or hydrophilic, vinyl monomers. As used herein, the term “hydrophilic monomer” describes a monomer which, when polymerized, yields a polymer that either dissolves in water, or is capable of absorbing at least 10%, by weight, of water under ambient (i.e., 20° C.) conditions. Similarly, as used herein, the term “hydrophobic monomer” describes a monomer, which when polymerized, yield a polymer that neither dissolves in water, nor is capable of absorbing at least 10% water, by weight, under ambient conditions. As shown in FIG. 2, examples of suitable monomers may include methacrylates, acrylates, styrenes, methacrylamides, acrylamides, silyl-containing monomers.

The gel scaffold 110 may include a side group. More specifically, a gel scaffold molecule, or a group of gel scaffold molecules, may have a side group, or multiple side groups. The side group functions to provide a binding site for the latent patterning material 120. The side group may be any desired side group that can be used for binding of the latent patterning molecules 120. Examples of potential side groups include, but are not limited to: carboxylic acids, sulfonic acids, phosphoric acids, primary amines, quaternary amines, amides, hydroxides, and/or sulfonates. Dependent on the implementation, the gel scaffold 110 may incorporate one, or multiple, side groups. Multiple side groups may enable binding of multiple types of latent patterning materials 120, other components (e.g., a masking component), and/or provide binding with different binding strengths (e.g., to enable a gradient effect binding).

In some variations where the gel scaffold 110 comprises vinyl monomers, the vinyl monomers may have the side group(s). Examples of side groups include: carboxylic acid, sulfonic acid, phosphoric acids, primary, secondary, tertiary and quaternary amines, hydroxyl, thiols and thioesters, amides and acetates. As used herein, side groups such as “carboxylic acids”, “sulfonic acids”, or “phosphoric acids” include the free acid moiety and corresponding metal salts of the acid moiety, as well as ester derivatives of the acid moiety, including without limitation alkyl esters, aryl esters and acyloxyalkyl esters. In some variations, the gel may be composed of naturally occurring polymer, such as agarose, alginate or other polysaccharides. In some variations, the gel may be composed of charged monomers, such as acrylic acid, 2-(dimethylamino)ethyl methacrylate, sulfonated monomers, or others.

In some variations the gel scaffold 110 may contain functional groups that enable binding of the latent patterning material 120. The functional group may be incorporated as part of the main chain of the gel scaffold 110 or as the side group of the gel scaffold. Functional groups may be susceptible to radical oxidation. In some variations, functional groups may be introduced to the gel scaffold 110 by radical polymerization of suitable vinyl monomers. Polymerization may be conventional (e.g., no control over polymer molecular weight) or controlled, where molecular weight of the resultant polymer making up the gel scaffold 110 is narrow and well-defined. Examples of controlled free radical polymerizations (cFRP) include reversible addition-fragmentation chain-transfer (RAFT) polymerization, nitroxide-mediated polymerization (NMP), and atom transfer radical polymerization (ATRP). In other variations, the functional group(s) may be introduced by chemical modification of the gel scaffold 110. Examples of functional groups that may be incorporated into the gel scaffold 110 include: carboxylic acids, amides, or primary amines or hydroxyl groups introduced by the polymerization of acrylic acids and acrylamide monomers. Other examples of functional groups that the gel scaffold 110 may contain include: phosphoric acids, quaternary amines, amides, hydroxides, cyclic anhydrides and succinimides, and/or sulfonates.

The system may include the latent patterning material 120. The latent patterning material 120 functions as the “latent pattern” for the nanofabrication, i.e., a temporary construction providing the architecture of the nanofabrication. In some variations, it may be desired to retain the latent patterning material 120, and thus, it may be implemented for longer periods if desired. The latent patterning material 120 may further function to bind the build material 130 in place, providing function similar to a mold. The latent patterning material 120 (also referred to as chromophore) may comprise latent patterning molecules, wherein each molecule may be composed of any desired type, or types, of subgroups. Herein, the term latent patterning material 120 may be used to refer to each individual latent patterning molecule, a group of latent patterning molecules, all latent pattern molecules, or any subset thereof. Thus, each latent patterning molecule 120, or group of latent patterning molecules, may have a gel binding region that binds the gel scaffold 110, and a material binding region that binds the build material 130. Additionally, the latent patterning molecules 120 may be photosensitive, such that the activity of latent patterning (e.g., gel binding) may be turned on or off by light. Each latent patterning molecule, or group of latent patterning molecules, may include other components as desired per implementation.

In some variations, the system may include multiple latent patterning materials 120. Different latent patterning materials 120 may be distinguished by the base molecules themselves, or their specific regions (e.g., build material binding region). For example, different latent patterning materials may bind different types of build material 130 (e.g., a first latent pattern material binds diamond and a second latent patterning material binds azides). In another example, different latent patterning materials 120 may have different activations. For example, two photosensitive latent patterning materials 120 may have different photosensitive regions. In one implementation a first latent patterning material that absorbs blue light and a second latent patterning material that binds yellow light. In another photosensitivity implementation, a first latent patterning material 120 that binds a first build material 130 may be enabled to bind to the gel scaffold 110 by light activation and a second latent patterning material that binds a second build material may lose its ability to bind to the gel scaffold by light activation.

The latent patterning material 120 may be photosensitive. That is, the latent patterning material 120 may comprise photosensitive molecule(s), and/or photosensitive regions, that enable the latent patterning material to absorb certain wavelengths of the electromagnetic spectrum. In some variations, the photosensitivity of the latent patterning material 120 is connected to the conjugation chemistry of the latent patterning material. The photosensitive region functions as a light sensitive region of the latent patterning material 120, wherein light, of the appropriate wavelength, on the photosensitive segment may be used to activate, or deactivate, the gel binding of the latent patterning material. Depending on the implementation, each latent patterning molecule may have one, or multiple, photosensitive regions, wherein each photosensitive region enables different activity (e.g., one light bandwidth may enable gel binding of a molecule and another bandwidth may enable a molecule to release the gel).

The photosensitive region may be sensitive to any desired wavelength, or bandwidth, of electromagnetic radiation, set by the chemistry. In some variations, the light sensitive region(s) may comprise sensitivity to a bandwidth that is in, or near, the visible spectrum (e.g., blue light, UV light, red light, infrared light, etc.). The photosensitive region may comprise a broad or narrow bandwidth, as desired and set by the chemistry. The photosensitive region may comprise any photochemistry. In many variations, the type of latent patterning material 120 may set the chemistry of the photosensitive region. Examples of the latent patterning material include: derivatives of xanthene dyes (e.g., fluoresceins, rhodamines, eosins), BODIPY, cyanines, pthalocyanines, anthracenes, coumarins, porphyrins, squaraines, squarylium and azobenzene. Dependent on implementation, the latent pattern material 120 may comprise any one, or combination, of these or other photochemistries.

The latent patterning material 120 may include, one or more, gel binding regions. The gel binding region may function to enable binding of the latent patterning material to the gel scaffold 110. In many variations, the gel binding region may bind the side group of the gel scaffold 110. In other variations, the gel binding region may non-specifically bind the gel scaffold 110 (e.g., a charged/polar gel binding region binding to a charged gel scaffold). i.e., a gel binding region (or gel binding site). The gel binding region may include a photosensitive region, wherein the photosensitive region may comprise any molecule(s) that can enable, or disable, gel binding. Depending on the type of latent patterning material 120, photo-activation may enable activation, or deactivation, of the latent patterning material binding.

The latent patterning material 120 may include a material binding region. The material binding region may function to enable binding of the build material 130. In some variations, the material binding region may comprise a conjugation chemistry (or conjugation site) that helps enable binding the build material 130, wherein the conjugation chemistry may enable binding the build material at the build material coordination site. Alternatively, the latent patterning material 120 may not have a conjugation chemistry segment. In one example, the build material 130, or the build material coordination site, may bind directly to the latent patterning material 120.

In some variations, the material binding region may be considered always “activated”. Alternatively, the material binding region may have an active and inactive conformation, such that build material 130 binding may be activated or deactivated. In one example, the build material binding region may be linked to a photosensitive region of the latent patterning material 120, such that build material 130 binding may be turned on or off by a light band on or near the appropriate wavelength. In another example, the material binding region may have an allosteric site, wherein binding of a compound to the allosteric site may turn on, or off, build material binding. The material binding region may comprise any molecule(s) that can enable, or improve, binding of the build material 130 to the latent patterning material 120. Examples of chemistries that may be incorporated in the material binding region include: primary amines, N-hydrosuccimide (NHS) and NHS esters, carboxylic acids including their free acids and corresponding metal salts, thiols/sulfhydryls, cyclic anhydrides such as succinic anhydrides and maleimides, alkenes, alkynes, azides, tetrazines, tetrazoles, nitrones, isocyanides, isocyanates, cyclooctynes including, dibenzocyclooctyne (DBCO), biarylazacyclooctynone (BARAC)s, biarylazacyclooctynones (BARAC)s, dimethoxyazacyclooctyne (DIMACs), monofluorinated (MOFO) and difluoronated (DIFO) cyclooctynes, biotins, avidins/streptavidins, proteins/antibodies/enzymes, oligonucleotides and nucleic acids, including deoxyribonucleic acid (DNA), ribonucleic acid (RNA), locked nucleic acids (LNA), peptide nucleic acids (PNA), lipids/hydrocarbons/fluorocarbons, and dendrimers.

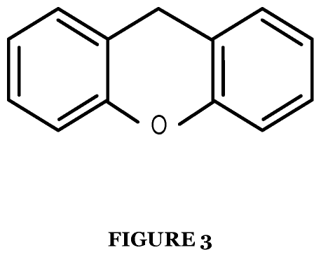

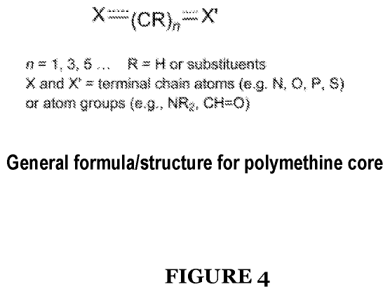

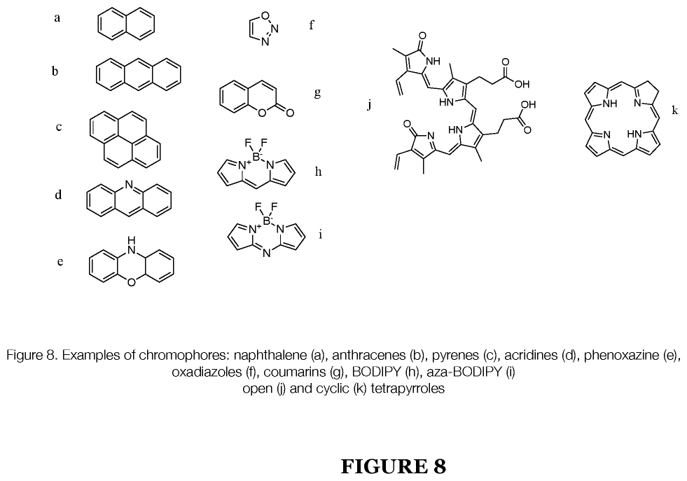

In some variations, the latent patterning material 120 may comprise a non-xanthene chromophore. As shown in FIG. 3, xanthene chromophores have a base structure of two benzene rings connected with an internal ring between them that has an oxygen. In these variations, the latent patterning material 120 may comprise a structure that does not include the xanthene base structure. Examples of classes of non-xanthene chromophores, as shown in FIGS. 4-8 include: polymethines (e.g., cyanines, squaraines), napthalenes, coumarins, oxadiazoles, anthracenes, pyrenes, phenoxazine, acridines, tetrapyrroles, and dipyrromethenes (e.g., BODIPY) and azadipyrromethenes (Aza-BODIPY) and their derivatives (as shown in FIG. 8).

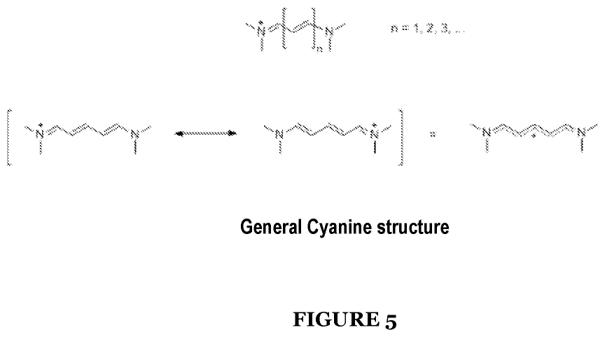

Polymethine dyes and their derivatives include polymethine dyes, where the chromophore unit is a conjugated C═C system (existing as an open-chain or in a ring), with an odd number of methine groups with functional groups at each end of the chain with a general formula as shown in FIG. 4. Examples of polymethine dyes and their derivatives include: cyanines (hemicyanines, streptocyanines, Cy3, Cy3.5, Cy5, Cy5.5, Cy7, Cy7.5, merocyanines) and their derivatives (e.g., Sulfonated derivatives). Cyanines are characterized by a conjugated π-system bridged by two nitrogen atoms with delocalized charges, with the general cyanine structure as shown in FIG. 5.

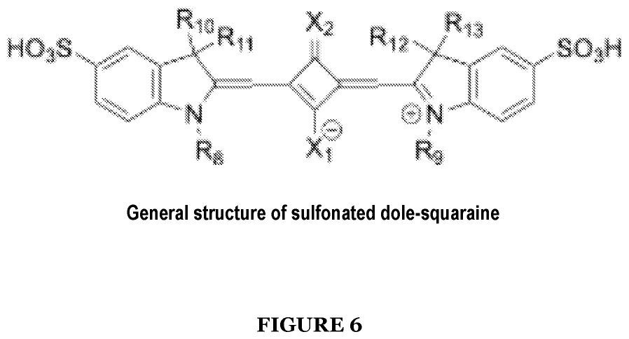

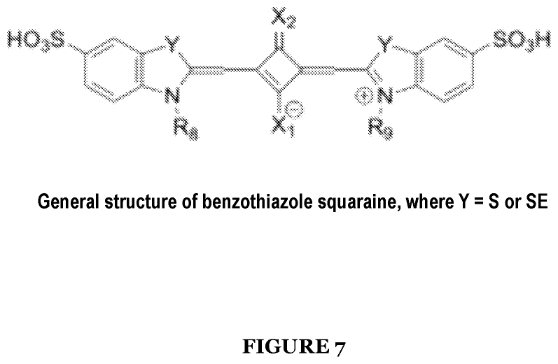

Squaraine dyes and their derivatives include: symmetric and unsymmetric indole-based squaraines bearing sulfonate groups at position 5 of indole rings, where X1, X2=O, S or a combination of the two, with a general formula as shown in FIG. 6; symmetric and unsymmetric benzothiazole-based squaraines bearing sulfonate groups at position 5 of indole rings, where X1, X2=O, S or a combination of the two, with a general formula as shown in FIG. 7. For benzothizole-based squaraines here, reactive substituent groups e.g., NHS, amine, —COOH, azide, alkyne, epoxide, etc. is attached via an alkyl spacer of length (CH2)n, n≥5 at position 1 of the benzothiazole ring(s) (R8 or R9). The term “symmetrical” means that each pair of R9 and R8 groups (see structure) is the same, such that the pattern of substituents on each benzothiazole ring in the compound is the same. The term “unsymmetrical” means that at least one of R8 and R9 is different from their counterpart substituent on the other benzothiazole group, such that the pattern of substituents on each benzothiazole ring is different. For symmetric and unsymmetric benzothiazole-based squaraines the term “symmetrical” means that each pair of R8, R10, and R11 groups (structure below) is the same, such that the pattern of substituents on each indole ring in the compound is the same. The term “unsymmetrical” means that at least one of R8, R10, and R11 is different from their counterpart substituent on the other indole ring, such that the pattern of substituents on each indole ring is different.

In some variations, the latent patterning material 120 includes a reactive group, wherein the reactive group may comprise any one, or combination, of the latent patterning material subcomponents. For example, the reactive group may comprise the gel binding region and the photosensitive region of the latent patterning material. The reactive group may function by selectively binding the gel scaffold 110, through a photoreaction of the latent patterning material and a reactive intermediate. In this manner, the reactive group functions to provide an additional control step for how the latent patterning material 120 can be patterned on the gel scaffold 110 by leveraging the interaction between the reactive group and the reaction intermediate. In many examples, the reactive intermediate comprises a small molecule capable of radical generation (e.g., oxygen). In these variations, the nanofabrication system may have additional components that enable control of the thermodynamic variables during operation of the system. Examples of these additional systems components include: an enclosed volume (e.g., a control volume limiting flow of solids, liquids, and/or gases into and out of the nanofabrication platform), a heating element (e.g., to control reaction temperatures), and a controlled ingress/egress for the reactive intermediate (e.g., to control the concentration of the reactive intermediate within the system).

The build material 130 may function as the material that the nanofabrication construct is made of. The build material 130 may bind to the latent patterning material 120. In some variations, the build material 130 binds directly to the latent patterning material 120. In other variations, the build material 130 binds to the material binding region of the latent patterning material 120. In other variations, the build material 130 binds directly to the latent patterning material 130 through a coordination chemistry of the build material coordination site. In other variations, the build material 130 binds to the material binding region of the latent patterning material 120 through the coordination chemistry.

The specific type of build material 130 may be implementation specific. In some variations, the build material 130 may comprise multiple, distinct, types of build materials (e.g., titanium dioxide and gallium phosphide). The only requirement for the build material 130 is a coordination chemistry that enables binding of a latent patterning material 120. As the build material 130 is the material composition of the final product, the binding requirement of the build material 130 may be typically addressed by the choice of the latent patterning material 120 having a material binding region with the appropriate chemistry. Examples of build material 130 types include: Metal chalcogenides, where the metal is Ge, Al, Sn, Pb, Sb, Bi, Ga, In, Tl, Cu, or a combination thereof and a chalcogen, such as, S, Se, Te or a combination thereof; Pnictides and resulting pnictide polymorphs of group XIII elements such as, B, Al, Ga, In, and Tl, or a combination thereof, and a pnictogen, such as N, P, As, and Sn; Metal oxides with the empirical formula MxOy, where M is a metal such as Bi, Sn, Cr, Co, Mn, Mo, Ti, Zn, Zr, Cu, Fe, Ni, Eu, Dy, Pr, Ce, Sm, or La; and carbon and its allotropes, silicon, germanium, tin, silicon carbide (3C, 4H, 6H, —SiC), silicon germanium, and silicon tin.

The build material 130 may include a coordination site. The coordination site functions as the region to bind the latent patterning material 120 (i.e., the appropriate coordination chemistry that binds to the latent patterning material). In many variations, the coordination site binding is highly selective, enabling binding of specific atoms or molecules only. Alternatively, the coordination site may be more general, enabling binding of families of molecules (e.g., chalcogenides). Examples of possible coordination chemistries include, but are not limited, to: silyl, sulfhydryl/thiol amine/ ammonia, carboxylic acid, iodide, bromide, chloride, fluoride, thiocyanate, nitrate, azide, oxalate, water, nitrite, isothiocyanate, acetonitrile, pyridine, ethylenediamine, 2,2′-bipyridine, 1,10-phenathroline, nitrile, triphenylphosphine, cyanide, and carbon monoxide. As the purpose of the coordination site is to bind the latent patterning material 120, the coordination site may additionally or alternatively have other chemical compositions. In variations, wherein multiple build materials 130 or multiple latent patterning materials 120 are incorporated, each build material 130 may have one or more distinct coordination sites (with different chemistries), wherein each distinct coordination site would potentially bind a specific, distinct latent patterning material. In some variations, the coordination chemistry may be incorporated directly onto the latent patterning material 120. In these variations, build material 130 may then bind to the latent patterning material 120 using the coordination chemistry incorporated on the latent patterning material.

In some variations, the system may further include a light source. The type of light source may vary dependent on implementation. The light source functions to photo-activate/deactivate the photosensitive region of the latent patterning material 120. Dependent on implementation, this may enable binding (or release) of the latent patterning material 120 to the gel scaffold 110 and/or the binding of the latent patterning material to the build material 130.

The light source may include one (or multiple) light emitters (e.g., one, two, three, diodes) of the same, or different types (e.g., incandescent, halogen, fluorescent, laser, LED, etc.). Preferably, the light source has sufficient accuracy such that light emission from the light source may be guided with sufficient precision to photo-activate/deactivate the latent patterning material 120 correctly to pattern a desired structure. In variations that include a mask, a broad scattered light source may be sufficient for the desired implementation, whereas for a non-mask nanofabrication, the light source may require nanometer precision.

Dependent on implementation, the light source may emit EM waves of any desired wavelength, bandwidth. Additionally, dependent on implementation, the light source may comprise a single, or multiple, light emitters, such that each emitter may emit EM waves at a desired wavelength with a desired bandwidth.

The light source may furthermore enable high throughput patterning. This may be part of basic operation of the nanofabrication platform, and/or as part of a lithography implementation. For high throughput patterning, the light source may have distinct operating modes, enabling fast and complex modes of light pulsing. For example, the light source may be enabled to emit light pulses in rapid fashion, such that the time between pulses is less than the excited triplet state lifetime of the latent patterning material 120. Dependent on the implementation, the triplet excited state lifetime may range from milliseconds (ms) picoseconds. Thus, depending on the implementation, the light source is preferably able to emit pulses of light with the appropriate separation between each light pulse. In one example, the latent patterning material 120 comprises Cy5, which is reported to have excited triplet state lifetime of approximately 10 μs. In this example, the light source may emit pulses with less than 10 μs separation between each pulse.

As part of an enhanced photon lithography implementation, the light source may comprise the appropriate light source for the implementation. For example, for a single photon lithography implementation, the light source may comprise a single laser (e.g., a diode). In another example, for a two-photon lithography implementation, the light source may comprise two lasers (e.g., a gas laser). That is, depending on implementation, single or multi-photon lithography techniques may be incorporated for gel binding. Dependent on implementation, the light source may enable any type of single photon lithography, such as: contact lithography, projection lithography, interference lithography, or phase mask lithography, tomographic lithography; and/or the light source may enable any type of multi-photon lithography, for example: point-scanned multi-photon lithography, multi-focal multi-photon lithography, holographic multi-photon lithography, or temporally focused multi-photon lithography.

As part of an enhanced photon lithography implementation, the system may further include a mask. The mask functions to demarcate the regions that require photo-activation. That is, the mask may be positioned between the gel scaffold 110 and the light source such that the mask may selectively block, reflect (or in some variations, alter the phase of) the light emitted from the light source, thereby preventing or reducing the light source from photo-activating the latent patterning material 120 in certain regions of the gel scaffold 110. In some variations, a mask equivalent may be implemented. For example, in some variations (e.g., for projection lithography or holographic lithography), a digital equivalent of the mask may be incorporated, wherein the digital equivalent mask may induce light passing through it to be partially or fully: blocked, reflected or to change phase. Examples of a digital mask equivalents include: a digital mirror device (DMD), spatial light modulator (SLM), and a phase mask (e.g., hologram). Additionally, the use of exposure time, or number of mask elements may be used to control the light dosage and therefore enable more or less patterning within a given region. In another variation, the system may be used for a lithography implementation where the light source may illuminate from more than one angle, using one, or multiple masks.

In many variations, the light intensity may also be incorporated for patterning, particularly pattern gradients. Light intensity may be modified, either directly, at the light source, or through implementation of the mask. In this manner a mask may be incorporated to create gradient patterns. In one example, a physical mask with varying density (e.g., increasing density along one axis) may be incorporated. A spatial pattern gradient may then be created, where less latent patterning material is bound to the region(s) that are less illuminated. In another example, a digital mask may be incorporated. In the same manner, by enabling reduced transmission of light through the digital mask, a gradient pattern may be created.

In some variations, the nanofabrication platform, more specifically the gel scaffold 110 may be adhered to a surface. In these variations the system further includes a binding group that adheres the gel scaffold 110 to the surface.

In many variations, the binding group consists of silane wherein the binding group functions to functionalize the surface. This may include silanization of a substrate (e.g., glass) using mono-silane coupling reagent to form a stable siloxane film to which the polymer adheres via covalent or electrostatic binding. Examples of silanes that may comprise the binding group include: alkyl silanes and amino silanes e.g. (3-Aminopropyl)triethoxysilane (APTES), (3-Aminopropyl)trimethoxysilane (APTMS) Through implementation of the binding group the system may adhere to a vast number of surfaces, of relatively any shape or roughness (e.g., flat, curved, bumpy surface, etc.). Examples of surfaces that the gel scaffold 110 may adhere to include: glass, silicon, metals/alloys, hard plastics (e.g., HDPE, polypropylene, acrylics).

In one example for a silane binding group, the binding group may be a mono-silane (e.g., trialkoxysilane). A mono-silane, with the general formula R′—(CH2)ₙ—Si(OR)₃, where R′ is a functional group that is capable of binding the gel scaffold 110, n i, and R is an alkyl group. Examples of the R include: Me, Et or propyl). Examples of R′ include: protonated amines, either primary, secondary, tertiary or quaternary (with a permanent charge) for electrostatic binding of the acrylic acid gel.

In another example for a silane binding group, the binding group may be a silane reagent with the general formula R′—Ln—Si(OR)₃, where R is an alkyl group (methyl, ethyl, etc.), L is a stable organic linker of length n made from stable bonds such as C—C, C—O or C—N, and R′ is a functional group capable of step-wise or chain-growth polymerization; such that it is capable of forming covalent bonds to the gel scaffold no in the presence of radical initiators or polymerization catalysts.

In an alternate variation, the binding group is a functional group with an opposite charge to the gel scaffold no. A functional group with an opposite charge to the gel scaffold 110 may enable formation of hydrogen bonds with the gel scaffold, or may be polymerized or otherwise covalently incorporated into the gel scaffold. For example, the desired surface may be coated cationic macromolecules/polymers, synthetic or natural, bearing opposite charges to the gel scaffold 110, to facilitate electrostatic binding of gel scaffold to the functionalized surface. Examples of such macromolecules include polycations like poly-1-lysine, polyethyleneimine (PEI), polymers containing quaternary amine salts, polymers of dimethylaminoethylmethacrylate (DMAEMA) etc.

In another variation, the binding group may comprise an entire polymer network, i.e., herein referred to as a surface binding polymer network. The surface binding polymer network may be embedded within and/or around gel scaffold 110. In some variations, the surface binding polymer network may include alkenes. The surface binding polymer network may be incorporated on, or within the gel scaffold 110 by washing the monomer components of the polymer network in the appropriate thermodynamic conditions such enabling polymerization of the monomer components. In some variations, the surface binding polymer network may already be capable of binding the desired surface (e.g., if a charged surface binding polymer network is incorporated to bind to a surface with the opposite charge). Alternatively, the surface binding polymer network may be further functionalized (e.g., with silanes or treated with plasma) to bind the desired surface.

As the system may cover a broad scope of implementations, a set of example system variations that describe the scope of the invention are now presented.

In a system variation A1, a system for a nanofabrication platform includes: a gel scaffold 110; a latent patterning material 120, that selectively binds the gel scaffold, comprising a non-xanthene based chromophore; and a build material, comprising a coordination site that binds the latent patterning material. In one example, the non-xanthene chromophore comprises a compound from the list consisting of: polymethine dyes, polymethine dye derivatives, squaraine dyes, squaraine dye derivatives, BODIPY-based dyes, and BODIPY-based dye derivatives. Examples of polymethine dyes and polymethine dye derivatives include: cyanines (hemicyanines, streptocyanines, Cy3, Cy5, Cy5.5, Cy7, Cy7.5, merocyanines) and their derivatives (e.g., Sulfonated derivatives). Examples of squaraine dyes and squaraine dye derivatives, include: symmetric and unsymmetric indole-based squaraines, and symmetric and unsymmetric benzothiazole-based squaraines bearing sulfonate groups. Other examples of non-xanthene dyes include: napthalenes, coumarins, oxadiazoles, anthracenes, pyrenes, phenoxazines, acridines, tetrapyrroles (e.g., open or cyclic tetrapyrroles), and dipyrromethenes (e.g., BODIPY) and azadipyrromethenes (Aza-BODIPY).

As part of the system variation A1, the gel scaffold 110 is selected from a group consisting of: agarose, acrylate, methacrylate, acrylamide, and silicone.

As part of the system variation A1, the build material 130 is selected from a group consisting of: Metal chalcogenides, where the metal is Ge, Al, Sn, Pb, Sb, Bi, Ga, In, Tl, Cu, or a combination thereof, and a chalcogen, such as, S, Se, Te or a combination thereof. Pnictides and resulting pnictide polymorphs of group XIII elements such as, B, Al, Ga, In, and Tl, or a combination thereof, and a pnictogen, such as N, P, As, and Sn. Metal oxides with the empirical formula MxOy, where M is a metal such as Bi, Sn, Cr, Co, Mn, Mo, Ti, Zn, Zr, Cu, Fe, Ni, Eu, Dy, Pr, Ce, Sm, or La; and carbon and its allotropes, silicon, germanium, tin, silicon carbide (3C, 4H, 6H, —SiC), silicon germanium, and silicon tin.

In a system variation A2, a system for a nanofabrication platform includes: a gel scaffold 110, a photosensitive latent patterning material 120, comprising a reactive group; and a build material 130, comprising a coordination site that binds the latent patterning material. The reactive group selectively binds the gel scaffold through a photoreaction of the latent patterning material and a reactive intermediate. This system functions to enable an improved gel binding by leveraging the interaction between the reactive group and the reactive intermediate. In this A2 variation, the system may further include a control volume, wherein the control volume functions that contains the gel scaffold, wherein the control volume is sufficiently enclosed to enable controlling the reactive intermediate concentration. In many examples, the reactive intermediate comprises a small molecule capable of radical generation. In some examples, the reactive intermediate comprises oxygen. In implementations of this example that include a control volume, the control volume may further include a controlled ingress (e.g., to enable pumping in of oxygen) and a controlled egress (e.g., to maintain internal pressure). In some implementations of system A1, the latent patterning material comprises a polymethine dye, or a polymethine dye derivative. In another implementation of system A1, the latent patterning material comprises squaraine, or a squaraine derivative. In another implementation of system A1, the latent patterning material comprises a BODIPY-based dye, or a BODIPY-based dye derivative.

In a system variation A3, the system comprises an enhanced lithography fabrication platform includes: a gel scaffold 110; a photosensitive latent patterning material 120; a build material, comprising a coordination site that binds the latent patterning material; and a light source enabled to provide extremely short light pulses. More specifically, the light source is enabled to provide short light pulses (of the appropriate wavelength), wherein the light pulses are separated by an amount of time that is shorter than the excited triplet state lifetime of the latent patterning material 120. The system variation A3 functions to leverage the excited triplet state of the latent patterning material 130 to provide a high throughput fabrication system.

That is, the light source preferably functions such that it can provide light pulses on the order of between milliseconds and picoseconds, dependent on the excited triplet state of the latent patterning material. As part of the functionality of the system, the system may have an implosion fabrication operating mode, wherein light source provides light pulses separated by an amount of time shorter than the excited triplet state lifetime of the latent patterning material 120. In one example, the latent patterning material comprises Sulfo-Cy5 with a triplet excited state lifetime on the order of ˜10 μs. For this example, in the implosion fabrication operating mode, the light source provides pulses in intervals of less than 10 μs. As part of an enhanced lithography fabrication platform, system variation A3 may include a pulsed light source (e.g., titanium sapphire or an erbium doped fiber laser light source), and/or a component that allows for creating bursts of multiple pulses. In a second example, the latent patterning material may comprise a squaraine, or squaraine derivative, with a triplet excited state lifetime on the order ranging approximately between 1 μs-250 μs. In this example, in the implosion fabrication operating mode, the light source provides pulses with pulse separations on the order of —0.1 μs-100 μs; i.e., the light source provides pulses with pulse separations less than triplet excited state lifetime of the squaraine, or the squaraine derivative.

In a system variation A4, the system for a nanofabrication platform includes: a gel scaffold 110; a photosensitive latent patterning material; a build material, comprising a coordination site that binds the latent patterning material; and a binding group that enables the gel to adhere to a surface. The A4 system variation functions to enable nanofabrication on a surface. That is, through the binding group, the gel scaffold 110 may be adhered to a surface during a nanofabrication process.

In many variations of the A4 system, the binding group consists of silane and/or siloxane. Silane and/or siloxane may enable silanization of the surface. In one implementation of the A4 system, the binding group comprises a mono-silane with the general R′—(CH2)ₙ—Si(O R)₃ where R′ is a functional group that is capable of binding the gel scaffold and R is an alkyl group and n≥1. In another example of the A4 system, the binding group comprises a silane reagent with the general formula R′—(Ln)—Si(O R)₃, wherein: R is an alkyl group, L is a stable organic linker with length n, consisting of C—C, C—O, or C—N bonds, and R′ is a functional group capable of step-wise or chain-growth polymerization, such that it is capable of forming covalent bonds with the gel scaffold.

In another variation of the A4 system, the binding group comprises a functional group that has an opposite charge to the gel scaffold 110.

As part of some implementations, such as system variations A2, A3, and A4, the latent patterning material 120 may comprise a non-xanthene chromophore. In a first implementation of these variations, the non-xanthene chromophore comprises a polymethine dye. In a second implementation of these variations, the non-xanthene chromophore comprises a polymethine dye or a polymethine dye derivative. Alternatively: for system variations A2, A3, and A4, the latent patterning material 120 may consist of at least one compound from the groups: polymethines (e.g., cyanines, squaraines, napthalenes, coumarins, oxadiazoles, anthracenes, pyrenes, phenoxazines, acridines, tetrapyrroles, and dipyrromethenes (e.g., BODIPY) and azadipyrromethenes (Aza-BODIPY).

As part of some implementations, such as system variations A1, A3, and A4, the latent patterning material 120 may include a reactive group, wherein the reactive group selectively binds the gel scaffold no through a photoreaction of the latent patterning material and a reactive intermediate. This reactive intermediate may comprise a small molecule capable of radical generation. In one implementation of system variations A1, A3, and A4, the reactive intermediate comprises oxygen.

As part of some implementations, such as system variations A1, A2, A3, and A4, the gel scaffold may comprise a hydrated gel (i.e., a swollen gel). In these implementations, the system may further include a mechanical spacer or be spin coated under controlled conditions that sets the gel scaffold no thickness. These implementations may be particularly useful for photolithography, and may be further incorporated as part of the enhanced lithography implementations. In one implementation, the swollen gel is implemented as part of a photolithography process. In a second implementation, the swollen gel is implemented as part of a multi-photon lithography process.

As part of some implementations, such as system variations A1, A2, and A3, the system may further include a binding group, wherein the binding group enables the gel scaffold 110 to adhere to a surface. In one example of these system variations, the binding group consists of silane or siloxane.

As part of some implementations, such as system variations A1, A2, A3, and A4, the system may further include a lithography mask. The mask may function to block, or reduce, light on designated regions of the gel scaffold. The mask may be a physical mask, or a digital mask composed of pixels that block, or reduce, light. In one implementation for systems A1, A2, A3, and A4, the mask comprises a digital micromirror device. In a second implementation for systems A1, A2, A3, and A4, the mask comprises a spatial light modulator. In a third implementation for systems A1, A2, A3, and A4, the mask comprises a phase mask.

### 3. Method

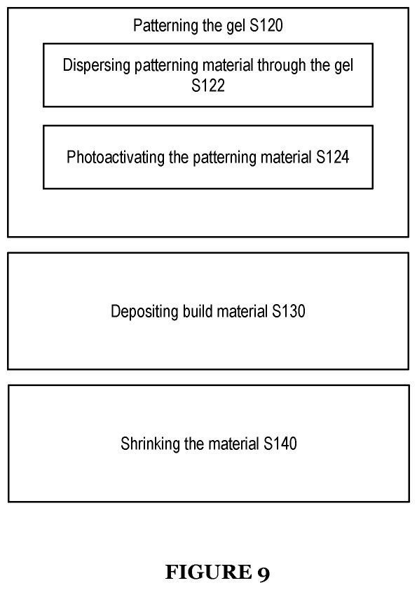

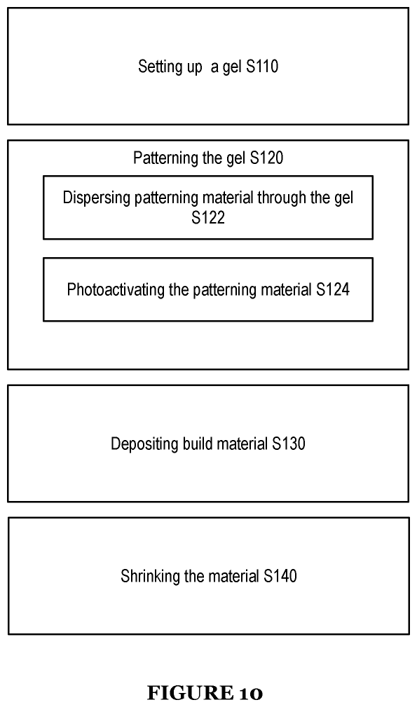

As shown in FIG. 9, a method for a three-dimensional nanofabrication includes: patterning a gel S120, comprising: dispersing a patterning material through the gel, binding build material to the patterning material, thereby constructing the three-dimensional fabrication, and shrinking the three-dimensional nanofabrication. Patterning the gel S120 further includes: dispersing a patterning material through the gel S122; and at distinct positions within the gel, photoactivating the patterning material S124, thereby causing the patterning material to selectively bind the gel at the distinct positions. In some variations, patterning the gel S120 may further include removing the unbound patterning material. The method functions in creating a desired composition/object composed of a desired build material within a desired gel matrix. More specifically, the method provides a means for mapping out an enlarged version of a desired fabrication on a light-sensitive patterning material (through light activation), and then building the enlarged fabrication by assembling the build material onto the light-activated patterning material. Furthermore, the method enables shrinking down the entire structure to the appropriate size. In some variations, as shown in FIG. 10, the method further includes setting up a gel S110. Setting up a gel matrix provides the scaffold network for the patterning process. Dependent on implementation, the method may comprise any one, multiple, or all steps of the method mentioned above. The method may be implemented with the system as described above, but may be implemented with any general system that meets the appropriate system criteria.

The method may be implemented in a broad range of fields. A plethora of compositions/objects with a broad range of functionalities and build materials may be fabricated incorporating the method. The method may be particularly useful in fields necessitating high precision nano-sized materials (i.e., nano-technologies). Examples include the field of electronics leading and the fabrication of electronic primitives (e.g. resistors, capacitors, inductors, solenoids, transformers, diodes, antennas, resonators, electromagnets, memristors, etc.) the field of optics and the fabrication of optic primitives (e.g. wave guides, prisms, gratings, fresnel lens, GRIN lens, meta-lens, lens arrays, zone plates, inverse-design structures, gain medium, photonic crystals, linear polarizer, circular polarizer, optical isolators, reflective optics, optical cavities), mechanics leading to the fabrication of mechanical primitives (e.g. gears, ratchets, springs, linear motors, rotary motors, structural lattices, mechanical metamaterials, ball and socket joints, hinges, chains, mechanical switches). Additionally, the method may be implemented for fabrication of more complex objects, such as complex motors, microchips, lasers, LEDs, diffractive neural networks, etc.

In some variations, the method includes setting up a gel Sno. Setting up a gel Sno, functions in creating a multidimensional scaffold for nanofabrication. Alternatively, the method may utilize a preexisting gel or other multidimensional scaffold for nanofabrication. The gel may be of any desired type that is non-reactive with the other components. In many variations, the gel type may be implementation dependent. Examples of gels include: agarose, acrylate (e.g. polyacrylate), methacrylates, acrylamide, and silicone.

In some variations, setting up the gel may include adhering the gel to a surface. Adhering the gel to a surface may function to enable method functionality on a surface. That is all method steps may be implemented while the gel is adhered to the surface (e.g., illuminating the gel, patterning the gel, shrinking the gel, etc.). Additionally, the surface may have a unique shape that may affect the build construction. Adhering the gel to a surface may comprise incorporating a binding group (e.g., silane, siloxane) that binds the desired surface and either binds, or is incorporated into the gel matrix.

In some variations, an additional polymer network may be set up. Setting up an additional polymer network may occur at any time after the initial setting up the gel 110 (e.g., before, during, or after patterning the gel 120; before, during, or after depositing the build material 130; before, during, or after shrinking the material 140. Setting up the secondary polymer network may function to help stabilize the patterning material and/or the build material.

In some implementations, the additional polymer network may be incorporated as a binding group. In these implementations, setting up an additional polymer network may incorporate a polymer network (i.e., a surface binding polymer network) into and/or on the gel that may enable the gel to bind a surface. Setting up the surface binding polymer network may comprise washing the gel with monomer components in the appropriate thermodynamic conditions such that the monomer components polymerize to form the surface binding polymer network. Alternatively, any other method of polymer incorporation may be implemented for setting up the surface binding polymer network. Dependent on the implementation, the surface binding polymer network may already be set to bind the desired surface (e.g., complementary polarity or charge of the surface binding polymer network and the surface). Additionally or alternatively, the surface binding polymer network must be prepared for surface binding. In one example, the surface binding polymer network is functionalized with silanes to enable glass binding. Alternatively, the surface binding polymer network is functionalized with plasma.

Block S120, which includes patterning the gel, functions to pattern (i.e., map out) the desired fabrication, by binding the patterning material to the gel. Patterning the gel S120 includes: dispersing the patterning material through the gel S122; and photo-activating the patterning material S124. Preferably, the patterning material is a photosensitive material, such that photoactivating the patterning material enables a change in interaction between the gel and the patterning material (e.g., binding, unbinding). In its simplest form, regions of the gel that have photo-activated patterning material may become fixed in place, or bound to the gel. By specifically photo-activating the patterning material in a manner to trace out the shape of the desired fabrication a mapping of the desired fabrication may be created by the bound patterning material. Unbound latent patterning material may then be washed away, leaving the desired patterning for the fabrication. For complex structures, patterning the gel S120, and its substeps, may be repeated multiple times until a final desired mapping of the fabrication is created.

The patterning material (also referred to as chromophore, conjugation material, or dye) used for patterning the gel S120 may be of any desired type, or types, of material. That is, the patterning material may be a single compound or multiple distinct compounds, patterned on to the gel. This compound, or compounds, may pattern over distinct regions of the gel, or may be interspersed. The type, or types, of patterning material, and their dispersion may be implementation specific.

The patterning material may include a single, or multiple, functional molecules or molecule segments, wherein each single, or multiple molecules provides the patterning material with a functional desired property (e.g., phosphorescence, photosensitivity, binding site(s), increased/decreased solubility, etc.). Heretofore any functional property may be referred to as a “segment”, wherein a segment enables a specific functional property and may equally refer to part of a molecule, a single molecule, or multiple molecules, without any loss of generality.

The patterning material may comprise a reactive group segment. The reactive group segment comprises a reactive group utilized to enable binding of the build material. The reactive group segment may comprise any molecule(s) that can enable binding of the patterning material to the build material. In some variations, the reactive group segment may be turned on, or off (e.g., by allosteric binding or photo-activation). In some variations, the reactive group segment is always active. In some variations, the reactive group segment binding may only be activatable such that binding only occurs once the reactive group segment has been activated (e.g., by photoactivation). In an alternative variation, the reactive group segment may be initially active, such that the build material may directly bind to the patterning material. Activating the reactive group segment (e.g., through photo-activation) may then release the build material, such that it can be washed away, enabling patterning a construction by “erasure”.

In some variations, the number of reactive groups may be amplified by depositing a material that contains multiple reactive groups. In these variations, the method may further include amplifying the reactive group by depositing a reactive group rich compound. Amplifying the reactive group may function to increase the rate, and/or ability, of the patterning material to bind the gel. In some examples, depositing a reactive group rich compound comprises depositing poly(amido)amine.

In some variations, the patterning material does not include a reactive group segment, or includes a suboptimal reactive group segment (i.e., a reactive group segment that does not enable sufficient binding with the desired build material). In these variations, the method may further include: priming the patterning material. Priming the patterning material functions to add, or modify, a reactive group segment to the patterning material, such that the build material may better bind to the patterning material. Priming the latent patterning material may comprise creating, or obtaining, the desired molecular sequence and binding it to the patterning material. Alternatively, priming the patterning material may comprise, using molecular techniques to modify the current reactive group segment to the desired sequence. Alternatively, priming the patterning material may comprise using recombinant techniques to create the DNA precursor of the desired molecular sequence prior to producing the protein.

The reactive group segment may comprise any molecule(s) that enable build material binding. Examples of the conjugation segments include: primary amines, NHSs, carboxylic acids, sulfhydrils, maleimides, alkenes, alkynes, azides, tetrazines, tetrazoles, difluorinated cycloocytne (DIFO), DIBOs, BARACs, DBCOs, biotins, avidins/streptavidins, proteins (e.g. antibodies/enzymes), nucleic acids (e.g. DNA, RNA, LNA, PNA), lipids (e.g. hydrocarbons, fluorocarbons), and dendrimers.

The patterning material may comprise a photosensitive segment. The photosensitive segment may be functionally connected to the gel binding segment. The photosensitive segment functions as a light sensitive region of the patterning material, wherein light, of the appropriate wavelength, may be used to activate, or deactivate, binding of the gel binding segment. Thus, the photosensitive segment enables patterning the gel S120 by photoactivating the patterning material. In some alternative variations, the photosensitive segment may enable binding or unbinding of the reactive group segment.

In some variations, the multiple distinct types of latent patterning material may be incorporated (e.g., two distinct patterning material types wherein each one is associated with a different build material through distinct coordination sites). These variations may have patterning material where each type of patterning material has a photosensitive segment that is sensitive to a distinct light bandwidth, thereby patterning a first patterning material with photoactivation by a first light bandwidth will not affect patterning a second patterning material with photoactivation by a second light bandwidth. This may enable patterning the gel S120 with distinct patterning material such that each material may later bind to a different build material.

The photosensitive segment may be “light” sensitive to any desired bandwidth of the electromagnetic radiation set by the chemistry of the photosensitive segment. In some variations, the light sensitive region may comprise sensitivity to a light bandwidth that is on or near the visible spectrum (e.g., blue light, UV light, red light, infrared light, etc.). The sensitivity may comprise a broad or narrow bandwidth, as desired and set by the chemistry. In variations where the gel binding segment may be both activated and deactivated, the photosensitive segment may be light sensitive to multiple, distinct regions of the visible spectrum. For example, red light may be used to activate gel binding and green light may be used to prevent, or reverse, gel binding.

The photosensitive segment may comprise any chemistry enabling light sensitivity, i.e., photochemistry. Examples of possible photochemistry molecules that may comprise the photosensitive segment include, but are not limited to: fluorescein, rhodamine, cyanines, squaraines, napthalenes, coumarins, oxadiazoles, anthracenes, pyrenes, phenoxazines, acridines, tetrapyrroles, and dipyrromethenes (e.g. BODIPY) and azadipyrromethenes (Aza-BODIPY) Dependent on implementation, the photosensitive segment may comprise any one, or combination, of these or other photochemistries.

The patterning material may comprise a gel binding segment. The gel binding segment may function in binding the gel. The gel binding segment may comprise any molecule(s) that can bind, or enable, binding of the gel. In some variations, the gel binding segment may be always active, such that the gel binding segment of the patterning material always binds to the gel. In one variation, the gel binding segment may be turned on, or off (e.g., by allosteric binding or photoactivation). In some variations, the gel binding segment may be “positively activatable”, such that binding only occurs once the gel binding segment has been activated. In a second variation, the gel binding segment may be “negatively activatable”, such that latent patterning material may initially bind to the gel, but through activation (e.g., photoactivation), the patterning material becomes unable to bind to the gel and unbinds from the gel. In a third variation, the gel binding segment may be both positively activatable and negatively activatable, such that the patterning material may be able to change conformations such that it can be made to bind and unbind from the gel. For example, the gel binding segment may be connected to one, or more, photosensitive segments sensitive to different bands of light. In this example, photoactivation by a first band of light (e.g., blue light) may activate the gel binding segment such that it can bind the gel, and photoactivation by a second band of light (e.g., red light) may deactivate the gel binding segment such that it cannot bind the gel.

In some variations, the method may include leveraging the reaction for gel binding by the patterning material. Dependent on the reactive group segment, the photoreaction of a patterning material (e.g., chromophore) and a reactive intermediate facilitates binding of the gel via a radical reaction. By controlling the concentration of the reactive intermediate, the rate of patterning material binding to the gel may be manipulated.

Block S122, which includes dispersing the patterning material through the gel, may be a component of patterning the gel S120. Dispersing the patterning material through the gel S122 functions to provide the infrastructure for creating the nanofabrication. In some variations, dispersing the patterning material through the gel S122 deposits the patterning material homogeneously throughout the gel. This may be done by flowing the patterning material through the gel until the gel is saturated with the patterning material. In negatively activatable variations, the gel binding segment of the patterning material binds to the gel to the level of saturation. In positively activatable variations, the gel binding segment needs to be activated for gel binding, and may thus diffuse freely through the gel.

Alternatively, dispersing the patterning material through the gel S122, may enable inhomogeneous deposition of the patterning material. For example, unidirectional flow (e.g., using microfluidics) may enable high concentration deposition on the side of the gel where the material enters the gel and low concentration deposition on the side of the gel where material flows out, creating a gradient of patterning material. Through the use of directional flows, any desired gradient deposition may be implemented dependent on the gel geometry. By limiting the flow over a certain time period, a latent patterning material concentration gradient may be created through the gel. Gradient deposition of the patterning material may enable forming gradients in the final nanofabrication (e.g., in the construction of optical primitives such as lenses).

Block S124, which includes photoactivating the patterning material, may be a component of patterning the gel S120. Photoactivating the patterning material S124 functions in mapping the shape of the structure of the fabrication with bound patterning material. That is, the bound patterning material may thus demarcate the shape and structure of the desired fabrication within diffusing unbound latent patterning material. Additionally, different concentrations of patterning material may also demarcate gradients in the desired fabrication. Dependent on the implementation, the demarcation may comprise the general shape/structure of the desired fabrication, or the negative (e.g., mold) of the general shape/structure of the desired fabrication. In preferred variations, unbound patterning material may be washed away. Photoactivating the patterning material S124, comprises shining a focused light, or light beam, of the appropriate wavelength such that desired photosensitive segments of the patterning material are activated. Photoactivating the patterning material S124 may include both spatial focus and exposure time of light beam(s). Spatial focus of light beam(s) may be used to physically shape the desired fabrication (or its negative space). The exposure time of light beams (i.e., length of time the beam is focused in a given region) may be used to “shape” the concentration of material in a given region—that is, enable deposition (or removal) of different concentrations of patterning material in a given region.

The effectiveness of photoactivating the patterning material may be significantly dependent on how light is administered to the patterning material. By leveraging the triplet excited state lifetime of the patterning material, the efficiency of photoactivating the patterning material may be significantly improved. In some variations, photoactivating the patterning material includes providing light pulses that are separated by an amount of time less than the triplet excited state of the patterning material. Dependent on the implemented patterning material this pulsing rate may vary. For chromophores, the lifetime of the triplet excited state is typically between microseconds and picoseconds.

In a first, positively activatable variation, photoactivating the patterning material S124, may enable binding (e.g., at the gel binding segment) of the patterning material to the gel. In a second, negatively activatable variation, photoactivating the latent patterning material S124 may enable release (e.g., at the gel binding segment) of the latent patterning material from the gel.

As part of the first variation, photoactivating the patterning material S124 may occur concurrent to dispersing patterning material through the gel S122, such that photoactivated regions with latent patterning material bind to the gel (e.g., at the activated gel binding segment), wherein other non-activated patterning material flows away, or is washed away.

In a first implementation of the first variation (positively activatable variation), block S124 is implemented such that the region that coincides with the actual design of the fabrication is photoactivated. That is, only regions that demarcate the shape and structure of the fabrication are photoactivated, and thus the patterning material stays bound only to the regions that demarcate the shape and structure of the fabrication.

In a second, negative, implementation of the first variation (positively activatable variation), block S124 is implemented such that the regions that do not coincide with the actual design of the fabrication are photoactivated. That is, only the negative regions, i.e., regions that do not coincide with the fabrication are photoactivated. In this second implementation, the latent patterning material binds to the negative of the desired fabrication, and thus demarcating the mold for the fabrication.

As part of the second, negatively activatable, variation, the patterning material may be initially dispersed throughout the gel such that the gel is fully or partially saturated and bound. Photoactivating the patterning material S124 may then be implemented to release the unwanted patterning material which may then be washed out, if desired.

In a first implementation of the second variation (negatively activatable variation), block S124 is implemented such that the regions that do not coincide with the actual design of the fabrication are photoactivated. That is, only the negative regions, i.e., regions that do not coincide with the fabrication are photoactivated, thereby releasing patterning material from the negative regions. In this first implementation, the patterning material stays bound to the region demarcating the desired fabrication, wherein the negatively photoactivated latent patterning material is washed away.

In a second, negative, implementation of the second variation (negatively activatable variation), block S124 is implemented such that the region that coincides with the actual design of the fabrication is photoactivated. That is, only regions that demarcate the shape and structure of the fabrication are photoactivated, thereby releasing the latent patterning material that demarcates the shape and structure of the fabrication. In this second implementation, the patterning material stays bound to the negative regions, i.e., regions that do not coincide with the fabrication, and thus demarcating the mold for the fabrication.

In “simpler” fabrication implementations, block S124 may be implemented a single time such that the structure of the fabrication is completely mapped onto the patterning material. Dependent on the complexity of the fabrication (e.g., multiple material fabrications, complex 3D structures, gradients, etc.), photoactivating the patterning material S124 may comprise a series of photoactivation steps wherein certain regions of the latent patterning material become binding activated/binding inactivated, multiple times, forming both the positive and/or negatives of regions of the fabrication. In some variations, patterning the gel S120 may additionally include alternating steps of depositing build material S130.

Photoactivating the patterning material S124 may additionally be used to provide the framework for creating gradients in the fabrication. Photoactivating the patterning material S124 preferably includes both spatial and temporal activation of the patterning material. By shining a light beam on a specific region of the patterning material for a longer period of time, and/or at a greater intensity, a greater concentration of the latent patterning material become light-activated in a given region, thereby enabling a greater concentration of patterning material bound to one region of the gel. Gradient implementations may be particularly useful for fabrication of lens and prisms. By implementing increasing/decreasing time periods of light activation over a given region of space, a concentration gradient of bound patterning material may be created.

In some variations, patterning a gel S120 may include incorporating lithography techniques. Incorporating lithography techniques may function to provide a more precise and coordinated method for photoactivating the patterning material S124, wherein the lithography technique helps determine how and where the patterning material is photoactivated. Incorporating lithography techniques may provide, up to nanometer precision in patterning the gel with the patterning material. Dependent on the implementation, this incorporating lithography techniques may comprise a photolithography technique (also referred to as one photon lithography), multi-photon lithography (also referred to as two, three, four, etc. photon lithography), or some combination of lithography techniques for photo-activating the latent patterning material S124. Additionally, dependent on the desired implementation, incorporating lithography techniques may be used to create either positive or negative patterning, or both. Dependent on implementation, incorporating lithography techniques may comprise utilization of a prefabricated “mask”.

In some variations, incorporating lithography techniques may include incorporating a single photon lithography technique. A single photon lithography technique may comprise using a photon emitter (i.e., a single light source such as an LED) for photoactivating the latent patterning material S124. Dependent on implementation, any single photon lithography technique, or multiple techniques, may be incorporated. Examples include: contact lithography, projection lithography (e.g., direct light projection, or tomographic lithography), interference/holographic lithography, and phase mask lithography.

In one implementation, incorporating lithography techniques comprises incorporating contact lithography. In this implementation, a prefabricated mask is implemented (wherein a mask may be fabricated prior to, or as part of the implementation). The mask may then be positioned in contact, or in proximity, to a photosensitive substrate such that light that passes through a light pattern is transferred through the mask and onto the photosensitive substrate. This can be achieved by illumination either from a point light source, a focused light source, a diffuse light source, or a collimated light source. Dependent on implementation, the light source may be incorporated from any desired angle.

In another implementation, incorporating lithography techniques may comprise incorporating projection lithography. In this implementation, the prefabricated mask may be implemented (wherein the mask may be fabricated prior to, or as part of the implementation). Alternatively, a digital equivalent mask (e.g., maskless lithography, micromirror device, spatial light modulator, or phase mask) may be incorporated. The mask may be used in order to create a 2D or 3D pattern of light that is projected onto the photosensitive substrate through the use of refractive, diffractive, or reflective optics. The optics may magnify, reduce, or directly transfer the pattern of light. Projection may be achieved by either full illumination of the mask at once or by scanning the region of illumination (e.g., a line) gradually over the mask and/or over the photosensitive substrate. Examples of projection lithography include: Extreme Ultraviolet Lithography, Immersion Lithography, and Direct Light Projection and projection tomography (a method for creating a 3D pattern by projecting light from multiple angles).

In some variations, incorporating lithography techniques comprise incorporating interference lithography (also referred to as holographic lithography). In these variations, the interference of two or more coherent beams of light in order to generate a periodic pattern in 2D or 3D. This interference may be generated by splitting and recombining beams through the use of reflective, refractive, or diffractive optics.

In some variations, incorporating lithography techniques comprise incorporating phase mask lithography. In this implementation, a prefabricated mask (wherein the mask may be fabricated prior to or as part of the implementation), or other structure, may be implemented. The use of the mask, or other structure, may be used to modulate the phase of light using a 2D or 3D structure in order to project a holographic image that is patterned into the photosensitive substrate.

In some variations, incorporating lithography techniques may include incorporating a multi-photon lithography technique (also referred to as direct laser writing technique). The multi-photon lithography technique may comprise using light for photoactivating (or deactivating) the patterning material S124, wherein two (or more) photon absorption is utilized to excite the photosensitive segment. Dependent on implementation, any number of photons may be used in multi-photon lithography, i.e., two-photon, three-photon, or n-photon excitation in order to pattern the photosensitive substrate. Dependent on implementation, any multi-photon lithography technique, or multiple techniques, may be incorporated. Examples include: point-scanned multi-photon lithography, multifocal multi-photon lithography, holographic multi-photon lithography, and temporally focused multi-photon lithography.

In some variations, incorporating lithography techniques comprise incorporating point-scanned multi-photon lithography. Incorporating point-scanned multi-photon lithography may include scanning a single point of multi-photon excitation within the photosensitive substrate mechanically, electro-optically, or acousto-optically.

In some variations, incorporating lithography techniques comprise incorporating multifocal multi-photon lithography. Multifocal multi-photon lithography may comprise using diffractive optical elements or lens arrays to generate multiple foci of multi-photon excitation, which then are projected into the photosensitive substrate and mechanically, holographically, electro-optically, or acousto-optically scanned to generate a pattern.

In some variations, incorporating lithography techniques comprise incorporating holographic multi-photon lithography. holographic multi-photon lithography may comprise using a digital element such as a DMD or SLM positioned in the Fourier plane of the optics to allow for the projection of multi-photon excitation patterns (i.e., holograms) into the photosensitive substrate. These projected holograms may be altered in order to generate any pattern in addition to being scanned around in the substrate mechanically, electro-optically, or acousto-optically.

In some variations, incorporating lithography techniques comprise incorporating temporally focused multi-photon lithography. Temporally focused multi-photon lithography may comprise using pulses of light that are temporally defocused and then refocused within the photosensitive substrate in order to create a pattern. The light pattern is generated by the use of either a mask or a digital mirror device which can be illuminated in its entirety for a full frame pattern, or partially, such as with lines/points of light scanned across the surface in order to transfer the pattern into the photosensitive material.

In some variations, setting up the gel may include setting up a swollen gel (i.e., a hydrated gel). In these variations, the method may further include mechanically deforming (e.g., compressing) the swollen gel before and during photoactivating the gel S124. Mechanical deformation of the swollen concurrent to photoactivation may function to provide a higher resolution patterning in the uncompressed dimensions.

Block S130, which includes depositing build material, functions to create the physical structure of the fabrication. Depositing build material S130 comprises flowing a desired build material through the gel. As the build material flows/disperses through the patterning material, the build material binds to the latent patterning material, thereby creating the physical structure of the fabrication. Dependent on the build material, the positional concentration of patterning material, and the implemented flow of the build material through the latent patterning material, the build material may be homogeneously or heterogeneously deposited onto the patterning material. In one variation, the build material binds directly to the patterning material. In a second variation, the build material binds to a reactive group segment on the patterning material. In a third variation, a coordination segment on the build material binds directly to the patterning material. In a fourth variation, a coordination segment on the build material binds a reactive group segment on the patterning material.

The build material may include a coordination segment. The coordination segment may function as molecule(s) that can bind one or more desired build material. In preferred variations, the coordination segment binding is highly selective, enabling binding of specific molecules only. In some variations, the coordination segment binding may be activatable. That is, the binding ability of the coordination segment may be turned on or off (e.g., by allosteric binding or photoactivation). In some variations, the coordination segment binding may only be activatable such that only binding occurs, once the coordination segment has been activated.

The coordination segment may comprise any desired chemistry. In many variations, the coordination segment may comprise an implementation specific chemistry, such that the coordination segment may bind the specific build material. Examples of the coordination segment composition include, but are not limited, to: silane/siloxane, sulfhydryl/sulfur, amine/ammonia, carboxylic acid, iodide, bromide, chloride, fluoride, thiocyanate, nitrate, azide, oxalate, water, nitrite, isothiocyanate, acetonitrile, pyridine, ethylenediamine, 2,2′-bipyridine, 1,10-phenanthroline, nitrile, triphenylphosphine, cyanide, and carbon monoxide. As the purpose of the coordination segment is to bind the build material, the coordination segment may additionally or alternatively have other chemical compositions. In variations, where multiple build materials are incorporated, each type of build material may have one, or more, distinct coordination segments, wherein each coordination segment type would potentially bind a distinct patterning material or the distinct reaction group segment of the patterning material.

In some variations, the build material does not initially include a coordination segment. In these variations, depositing build material S130 may include binding a coordination segment to the build material. Binding a coordination segment to the build material functions to enable, or improve, ligand binding to the patterning material.

In some variations, depositing build material may further include adding, or modifying, the chemistry of the reactive group segment of the patterning molecule. Adding, or modifying, the chemistry of the reactive group segment of the patterning molecule may function to improve build material binding. As deemed necessary, adding, or modifying, the reactive group segment may be performed multiple times until a reactive group segment is obtained with the desired binding capability.

In some variations, binding build materials to the patterning material includes depositing a non-metal enhancer. The non-metal enhancer may function to enable the build material to grow on the patterning material. In this manner, the build material may be allowed to grow outwards, allowing build material sites to grow out and connect to each other. In some implementations, this may enable build material to form and solidify prior to, during, or after the shrinking the gel. Dependent on implementation, the method may further include depositing build material until the build material bridges adjacent patterning material binding sites. Depositing build material may comprise depositing metal, and/or, non-metal build material, wherein either type may be enabled to grow until the build material bridges adjacent patterning material binding sites. In some variations, the build material, metal and/or nonmetal, may be allowed to grow beyond adjacent patterning material binding sites. In one example, the non-metal enhancer comprises a chalcogenide.

Depositing build material S130 may be deposited in a manner wherein the build material is deposited as a concentration gradient. That is, a certain region may have a greater concentration of the build material as compared to a different region of the fabrication. Concentration gradients of build material may be implemented through inhomogeneous patterning material dispersion through the gel and thus inhomogeneous dispersion of the build material which binds the patterning material. Through patterning material concentration, activated patterning material concentration, or build material flow, concentration of build material throughout the fabrication may be modified as desired.

Dependent on the implementation, depositing build material S130 may include depositing a single type, or multiple types of build material. Dependent on implementation, depositing build material S130 may occur concurrent to, or after, patterning the gel S120. In some implementations, depositing build material S130 may occur multiple times (e.g., separately for each different build material, or to create layered fabrications).

Depositing build material S130 may include depositing any type or types of build material, as desired per implementation. The desired build material may only be limited by the choice of coordinating segment(s) of the build material that is able to bind the patterning material. Examples of possible build materials include, but are not limited to: Metal chalcogenides, where the metal is Ge, Al, Sn, Pb, Sb, Bi, Ga, In, Tl, Cu, or a combination thereof, and a chalcogen, such as, S, Se, Te or a combination thereof. Pnictides and resulting pnictide polymorphs of group XIII elements such as, B, Al, Ga, In, and Tl, or a combination thereof, and a pnictogen, such as N, P, As, and Sn. Metal oxides with the empirical formula MxOy, where M is a metal such as Bi, Sn, Cr, Co, Mn, Mo, Ti, Zn, Zr, Cu, Fe, Ni, Eu, Dy, Pr, Ce, Sm, or La; and carbon and its allotropes, silicon, germanium, tin, silicon carbide (3C, 4H, 6H, —SiC), silicon germanium, and silicon tin.

Through blocks S120 and S130 complex structures with multiple types of build material may be created, with potentially any desirable geometries. For example, in the fabrication of a layered block made of two different types of build materials, wherein each layer is completely surrounded by an exterior layer: A first patterning material for a first material (e.g. includes a reactive group segment that binds the first material) is dispersed through the gel while the region of the desired deposition of the first layer is photoactivated, thereby causing the first patterning material to bind to the “first layer” region of the gel and allowing the rest of the patterning material to wash away. A second patterning material for a second building material (e.g., that includes a reactive group segment that binds the second material) is then dispersed through the gel while the region of the second material is photoactivated, thereby causing the second patterning material to bind to the “second layer” of the gel and allowing the rest of the patterning material to wash away. Additional layers of patterning material may be added in the same manner. Once patterning of the gel S120 is completed, the first and second build material may then be flown through the gel simultaneously or sequentially. The first build material may then bind and fill the first layer region (i.e., binding to the conjugation segment for the first material) and then the second build material may be flown through the gel to bind and fill the second layer region, etc.

In an alternative variation for constructing the previous example (for the multi-layered block), patterning material may be implemented with distinct photosensitive segments associated with distinct gel binding segments. That is, the first patterning material may additionally comprise a first gel binding segment (e.g., activated by blue light) and the second patterning material may additionally comprise a second gel binding segment (e.g., activated by yellow light). By simultaneously photoactivating with both blue and yellow light (on the appropriate desired regions), all patterning material may be patterned simultaneously. To prevent the unbound second material from accidentally becoming trapped within the first layer, depositing build material S120 may be implemented once for the first build material such that the first layer is completely bound and filled, and then depositing the second material to completely bind and fill the second layer of the multi-layered block.

Block S140, which includes shrinking the material, functions to enable patterning and fabrication at a high resolution and then to reduce the size of the fabrication to the appropriate size, enabling a high precision fabrication. Shrinking the material S140, may include adding acid, salt, and/or a different solvent causing the gel to shrink, thereby causing the fabrication bound to the patterning material embedded in the gel to also shrink. In preferred variations, shrinking the material may reduce the size of fabrication over twenty fold. For example, an object may be created at 5 micrometer resolution and then shrunk down to 500 nanometers. Examples of other shrinking methods that may be used for shrinking the material S140 include: a chemical reaction that modifies the polymer (e.g., converting charged groups on the backbone to hydrophobic uncharged groups, or creating additional crosslinks); a photoisomerization or photoreaction that changes the solubility or charge of the polymer backbone; incorporating an electrochemical change that modifies the charge or solubility of the polymer backbone; changing the gel temperature; drying in air, or creating a N2, vacuum, or another non-solvent environment; or adding and additive to the external solvent that changes the chemical potential of the solvent.

In some variations, the method may further include post-processing the build material. Post-processing the build material functions to modify the build material closer to a functional form for use. Dependent on implementation, this may occur any time after deposition of build material has started. In one variation, post-processing may occur concurrent to depositing build material 130. In another variation, post-processing may occur after one round of depositing build material (e.g., one layer of build material may be deposited, post-processing occurs, and another layer of build material is then deposited). Examples of post-processing steps that may be implemented include: metal conversions (i.e., converting build material metals), removing the gel scaffold, coating the build material, tempering the build material, etc.)

In some variations, wherein the build material comprises a metal, post-processing the build material includes converting the metal build material. In a first example, converting the metal converts the metal build material into a metal chalcogen (e.g., sulfide, selenide, telluride). Dependent on implementation, the metal chalcogen may then be converted to a second metal (e.g., cadmium, zinc, lead, tin, copper, or mixtures of these). In a second example, converting the metal, converts the metal build material into a metal oxide.

In one implementation of the first example of converting the metal build material a silver is converted to a silver chalcogen, and is then converted to a second metal (e.g., zinc sulfide, cadmium sulfide etc.), where conversion takes place in a range of solvents.

In some variations, post-processing the build material may include desolvating the gel. Desolvating the gel may include freeze drying, or super-critical drying of the gel, while the gel is in a fully swollen, or partially swollen state. Super-critical drying the gel may include using a solvent to dry the gel. Examples of solvents for super-critical drying include: ethanol, acetone, acetic acid, formic acid, etc. Dependent on implementation, freeze drying the gel may occur in the presence of a cryo-protentent agent. Alternatively, freeze drying the gel may occur without the cryo-protentent agent.

In some variations, post-processing may comprise removing a polymer network (e.g., the gel or additional polymer network.). Particularly in variations that include adding an additional polymer network, removing a polymer network may comprise removing the first, and/or any additional polymer network. Removing a polymer network may function to provide a new “environment” for the build; potentially for further processing or building. Dependent on implementation, removing a polymer network may occur prior to, during, or after patterning the gel; prior to, during, or after depositing the build material; and/or prior to, during, or after shrinking the gel. In one example that includes embedding an additional polymer network in the gel, removing a polymer network may remove the gel. In another example that includes embedding an additional polymer network in the gel, removing a polymer network may remove the additional polymer network.

The method may be particularly useful for fabrication of simple and complex optical components such as GRIN elements, diffractive elements, refractive surface geometries, meta-optical elements, magneto-optical elements, electro-optical elements, etc. This may be particularly the case for lithography implementations, and or use of pulsing fabrication techniques. Optical components may be constructed from any build material. Dependent on the desired implementation, the build material may be preferably sufficiently translucent, and/or reflective. In one optical component fabrication implementation, binding built material to the patterning material may include generating a refractive index (RI) contrast. In this manner, the refractive index contrast may be generated by deposition of the appropriate build material. In another optical component fabrication implementation, the refractive index may be generated through ion exchange between materials. In some variations, the method may enable fabrication of multiple components together.

For example, the method may enable construction of an optical structure that has both a refractive and a diffractive lens. In one example, the optical structure with both a refractive index and diffractive lens is made using one-photon lithography with a mask. In another example, the optical structure is a metasurface on the curved surface of a traditional refractive lens (e.g., a metasurface that corrects the spherical aberration of a spherical lens). In one implementation, the optical structure metasurface is made with two-photon lithography inside of a shaped hydrogel (with or without a mask). In some examples of the metasurface optical structure, the optical structure comprises multiple layers of optical metasurfaces (e.g., patterned with two-photon lithography). In another example, the optical structure comprises a thermal Mach Zehnder Interferometer with an integrated electrical resistance heating element (e.g., patterned with two-photon lithography). In another example, the optical structure comprises an optical isolator formed by combining optical polarizers with an integrated magneto-optical Faraday rotator.

As part of constructing optical components with a refractive index contrast, the method may further create a spatially dependent refractive index, i.e., a refractive index contrast. The method may thus enable construction of components with a large refractive contrast (e.g., >0.05 n). In one example, a spatially dependent refractive index with a large refractive index contrast is constructed by converting the build material to a metal chalcogenide. In another example, a spatially dependent refractive index with a large refractive index is achieved by amplifying the patterning material reactive group (e.g., by addition/amplification of poly(amido)amine).

Herein we provide an example for the fabrication of a multi-layer diamond prism block such that each layer has a different refractive index (due to a concentration gradient of diamond), thus creating an object with different speeds of light propagation in different directions. Starting with a pre-made gel, a patterning material is dispersed through the gel with a conjugation segment that binds diamond. A beam of light (attuned to activate the gel binding segment of the latent patterning material) is directed for a short amount of time into the region consisting of the desired top layer of the prism. The beam of light is then directed, for sequentially longer times, into each layer, going down the layers of the desired prism shape. Once finished, patterning material is present throughout the desired prism region, with decreasing concentrations going from the top layer of the prism to the bottom of the prism. Additional, unbound patterning material is washed away. Diamond material is then deposited throughout the gel, binding to the patterning material and creating the desired prism shape. In accordance with the patterning material, lower concentrations of diamond build material are deposited on the top part of the prism with increasing concentrations of diamond going to the bottom. Excess diamond material is washed away. Acid is then added to shrink the gel and reduce the size of the prism an order of magnitude. Once completed, solvent is added to wash away the gel and the latent patterning material, leaving the diamond prism.

A sample construction for an integrated refractive and meta-optical lens is herein presented as a second example. Setting up the gel sno comprises, setting up a swollen gel and adhering the gel to a surface (e.g., glass). Patterning the gel S120 then comprises using a chromophore (e.g., sulfo-Cy5) to pattern the appropriate shape of the gel. Patterning may occur using two-photon lithography to create the meta-surface pattern inside the gel. Once the unpatterned (unbound) chromophore is washed away, the patterned chromophore is then reacted with a seed nanoparticle (e.g., nanogold). Depositing the build material S130 then comprises depositing build material (e.g., silver) on the seed particles. Through an ion exchange process, the silver may be converted into a HRID material (e.g., CdS or ZnS). Shrinking the material S140 is then implemented to shrink and dehydrate the gel. Implementation specific post-processing may then be used for preparation of the lens. In this implementation, post-processing may first include dehydrating the gel, and then grinding and polishing the construct to form a refractive lens with the desired metasurface embedded within it.

In a method variation B1, a method for three-dimensional nanofabrication includes: patterning a gel, binding build material to the patterning material, and shrinking the three-dimensional nanofabrication. Patterning the gel may further include: dispersing a patterning material through the gel, at a distinct position within the gel, photoactivating the patterning material, thereby causing the patterning material to selectively bind the gel at the distinct position; and removing the unbound patterning material. Photoactivating the patterning material may further include: activating a reactive intermediate that facilitates the patterning material binding to the gel via a reactive group. This method variation may function to enable adjusting the reactive intermediate to modify the method output. In some examples, activating the reactive intermediate comprises radical generation. Dependent on desired implementation, the method may further include adjusting the reactive intermediate concentration. For example, in one implementation, wherein the reactive intermediate is oxygen. Adjusting the reactive intermediate concentration may be incorporated (e.g., by pumping in oxygen into an enclosed nanofabrication platform) to improve the efficiency of the method. In one implementation of method variation B1, the patterning material may comprise a polymethine dye that contains a donor-accepted bridge that interacts with the reactive intermediate.

In a method variation B2, a method for three-dimensional nanofabrication includes: patterning a gel, binding build material to the patterning material, and shrinking the three-dimensional nanofabrication. Patterning the gel may further include: dispersing a patterning material through the gel, at a distinct position within the gel, photoactivating the patterning material, comprising directing pulses of light that are separated by an amount of time shorter than the excited triplet state lifetime of the patterning material, causing the patterning material to selectively bind the gel at the distinct position; and removing the unbound patterning material. By leveraging the lifetime of the excited triplet state of the patterning material, this method functions to provide a high through-put fabrication with efficient binding the patterning material to the gel. This method may be particularly useful to enable enhanced photon lithography techniques.

In a method variation B3, a method for three-dimensional nanofabrication includes: setting up the gel patterning the gel, binding build material to the patterning material, and shrinking the three-dimensional nanofabrication. Setting up a gel may further include adhering the gel, via a binding group, to a surface. This method functions to enable nanofabrication on a fixed surface, wherein all other method steps may occur while the gel is adhered to the surface (including shrinking the material S140). In one example of system variation B3, adhering the gel to a surface includes using a binding group consisting: silane or siloxane, to functionalize the surface. In a second example, adhering of system variation B3, adhering the gel includes adhering the gel using a binding group with an electrical charge opposite to the charge of the gel, thereby incorporating the binding group into the gel.

As part of some implementations, such as the method variations, B2 and B3, the method may wherein photoactivating the patterning material includes activating reactive intermediate that facilitates the patterning material binding to the gel via the reactive group of the patterning material. In some examples, the patterning material comprises a polymethine dye that contains a donor-acceptor bridge that interacts with the reactive intermediate.

As part of some implementations, such as the method variations, B1, B2, and B3, the method further includes amplifying the reactive group by depositing a reactive group rich compound. Amplifying the reactive group may function to increase the rate, and ability, at which the patterning material binds the gel. In one example, depositing a reactive group rich compound comprises depositing poly(amido)amine.

As part of some implementations, such as the method variations, B1, B2, and B3, binding build material to the patterning material comprises depositing a non-metal enhancer. The non-metal enhancer may enable the build material to grow on the patterning material. Dependent on implementation, each method variation may further include depositing build material until the build material bridges adjacent patterning material binding sites. In one implementation of each method variation, depositing a non-metal enhancer comprises depositing a chalcogenide, and enabling the build material to grow. The deposited build material may be a metal, or non-metal, which would then be deposited until the build material bridges adjacent patterning binding sites.

As part of some implementations, such as the method variations, B1 and B3, photoactivating the patterning material may include directing pulses of light at the distinct position within the gel. Directing pulses of light may leverage the lifetime of the triplet excited state of the patterning material to enable high through-put patterning of the gel. In some examples, the directing pulses of light comprises directing pulses of light separated by an amount of time that is shorter than the excited triplet state lifetime of the patterning material. In some implementations, the patterning material may comprise cyanine, and the directing pulses of light comprises directing pulses of light separated by less than 10 microseconds.

As part of some implementations, such as the method variations, B1, B2, and B3, wherein the build material comprises a translucent material, the binding build material to the patterning material may include generating a refractive index. In one example, generating a refractive index includes generating a spatially dependent refractive index. More specifically, in some implementations, generating a spatially dependent refractive index using dielectric materials. Dependent on implementation, generating a spatially dependent refractive index may include generating a refractive index contrast of greater than 0.050. In another example, generating a spatially dependent refractive index may include generating a spatially dependent refractive index by converting the build material into a chalcogenide. Additionally or alternatively, generating a spatially dependent refractive index may include amplifying a reactive group by depositing poly(amido)amine.

As part of some implementations, such as the method variations B1, B2, and B3, wherein the gel comprises a hydrated gel (i.e., a swollen gel), pattering the gel may include mechanically compressing the gel in one dimension. Compressing the gel in one dimension may function to improve patterned resolution in the uncompressed dimensions. Mechanically compressing the gel may be quite useful for lithography techniques. In one example the method may further include using one-photon lithography while compressing the gel in one dimension. In an alternate example, the method may further include using two-photon lithography while compressing the gel in one dimension.

As part of some implementations, such as the method variations B1 and B1, the method may include setting up the gel, wherein setting up the gel further includes adhering the gel to a surface, via a binding group. In one example of these variations, adhering the gel to a surface comprises using a binding group consisting: silane and/or siloxane, to functionalize the surface. Alternatively, adhering the gel to a surface may include using a binding group with an electrical charge of opposite charge to the gel, thereby incorporating the binding group to the gel.

As part of some implementations, such as the method variations B2 and B3, wherein the build material comprises first a metal, the method may further include converting the first metal to a metal chalcogen, on the patterning material. Additionally, in some implementations, the method may further include converting the metal chalcogen to a second metal.

As used herein, first, second, third, etc. are used to characterize and distinguish various elements, components, regions, layers and/or sections. These elements, components, regions, layers and/or sections should not be limited by these terms. Use of numerical terms may be used to distinguish one element, component, region, layer and/or section from another element, component, region, layer and/or section. Use of such numerical terms does not imply a sequence or order unless clearly indicated by the context. Such numerical references may be used interchangeably without departing from the teaching of the embodiments and variations herein.

As a person skilled in the art will recognize from the previous detailed description and from the figures and claims, modifications and changes can be made to the embodiments of the invention without departing from the scope of this invention as defined in the following claims.

1. A system for a nanofabrication platform comprised of:
a gel scaffold;
a latent patterning material, that selectively binds the gel scaffold, comprising a non-xanthene based chromophore; and
a build material, comprising a conjugation chemistry that binds the latent patterning material.

2. The system of claim 1, wherein the latent patterning material further includes a reactive group, wherein the reactive group selectively binds the gel scaffold through a photoreaction of the latent patterning material and a reactive intermediate.

3. The system of claim 2, wherein the reactive intermediate comprises a small molecule capable of radical generation.

4. The system of claim 3, wherein the reactive intermediate comprises oxygen.

5. The system of claim 4, wherein the latent patterning material is a polymethine dye.

6. The system of claim 5, wherein the polymethine dye consists of squarine, or a squarine derivative.

7. The system of claim 5, wherein the latent patterning material further includes a donor-acceptor bridge.

8. The system of claim 11, wherein the gel scaffold comprises a hydrated gel (i.e., a swollen gel), and wherein the system further comprises a mechanical spacer that sets the gel scaffold thickness.

9. The system of claim 1, wherein the system further comprises a binding group that enables the gel scaffold to adhere to a surface.

10. The system of claim 9, wherein the binding group consists of silane or siloxane.

11. The system of claim 1, further comprising a mask, wherein the mask blocks, reduces, or redirects, light on designated regions of the gel scaffold.

12. The system of claim 11, wherein the mask comprises a digital mask composed of pixels that block, or reduce, light.

13. The system of claim 12, wherein the mask is a digital micromirror device.

14. The system of claim 12, wherein the mask is a spatial light modulator.

15. The system of claim 12, wherein the mask is a phase mask.

16. The system of claim 1, wherein the latent patterning material is selected from the group consisting of: polymethines or dipyrromethenes

17. The system of claim 16, wherein the latent patterning material comprises: cyanines.

18. The system of claim 17, wherein the latent patterning material comprises: hemicyanines, streptocyanines, Cy3, Cy3.5, Cy5, Cy5.5, Cy7, Cy7.5, merocyanines, and their sulfonated derivatives.

19. The system of claim 16, wherein the latent patterning material comprises: squaraines and their derivatives (e.g., sulfonated derivatives).

20. The system of claim 19, wherein the latent patterning material comprises: symmetric and unsymmetrical indole-based squaraines, symmetric and unsymmetric benzothiazole-based squaraines, squaryliums and their sulfonated derivatives.

21-243. (canceled)
